(19) United States
(12) Patent Application Publication
(10) Pub. No.: US 2016/0343806 A1
(43) Pub. Date: Nov. 24, 2016

(54) INTERFACE PASSIVATION LAYERS AND METHODS OF FABRICATING

(71) Applicants: GLOBALFOUNDRIES Inc., Grand Cayman (KY); INTERNATIONAL BUSINESS MACHINES CORPORATION, Armonk, NY (US); LAM RESEARCH CORPORATION, Fremont, CA (US)

(72) Inventors: Shariq SIDDIQUI, Albany, NY (US); Jody A. FRONHEISER, Delmar, NY (US); Murat Kerem AKARVARDAR, Saratoga Springs, NY (US); Purushothaman SRINIVASAN, Clifton Park, NY (US); Lisa F. EDGE, Westlake Village, CA (US); Gangadhara Raja MUTHINTI, Albany, NY (US); Georges JACOBI, Malta, NY (US); Randolph KNARR, Voorheesville, NY (US)

(73) Assignees: GLOBALFOUNDRIES INC., Grand Cayman (KY); LAM RESEARCH CORPORATION, Fremont, CA (US); INTERNATIONAL BUSINESS MACHINES CORPORATION, Armonk, NY (US)

(21) Appl. No.: 14/718,402

(22) Filed: May 21, 2015

(51) Int. Cl. H01L 29/161; H01L 29/51; H01L 29/423; H01L 29/66; H01L 23/29; H01L 23/31; H01L 21/311; H01L 29/78; H01L 21/02

(52) U.S. Cl. CPC H01L 29/161; H01L 29/78; H01L 29/513; H01L 29/517; H01L 29/42364; H01L 21/02532; H01L 21/02236; H01L 21/02175; H01L 23/291; H01L 23/3171; H01L 21/31111; H01L 29/66477

(57) ABSTRACT

Methods for fabricating interface passivation layers in a circuit structure are provided. The method includes forming a silicon-germanium layer over a substrate, removing a native oxide layer from an upper surface of the silicon-germanium layer, and exposing the upper surface of the silicon-germanium layer to an ozone-containing solution, resulting in an interface passivation layer with a higher concentration of germanium-dioxide present than germanium-oxide. The resulting interface passivation layer may be part of a gate structure, in which the channel region of the gate structure includes the silicon-germanium layer and the interface passivation layer between the channel region and the dielectric layer of the gate structure has a high concentration of germanium-dioxide.

### FIELD OF THE INVENTION

The present invention relates to integrated circuits and to methods of manufacturing integrated circuits, and more particularly, to interface passivation layers and methods for fabricating interface passivation layers of gate structures.

### BACKGROUND OF THE INVENTION

The high electrical carrier mobility exhibited in silicon-germanium semiconductor materials makes them attractive for use as a channel material in metal-oxide semiconductor (MOS) transistors, such as metal-oxide semiconductor field-effect transistors (MOSFETs). One of the challenges in fabricating a silicon-germanium MOSFET is the formation of a high-quality, defect-free interface passivation layer (IPL) between the gate dielectric and the silicon-germanium channel material. Silicon-germanium generally forms a native oxide layer on its surface, but such a native oxide layer may form a large number of defects at the interface and have an uneven surface texture, among other properties that make the native oxide material a poor interface passivation layer.

### BRIEF SUMMARY

Various shortcomings of the prior art are overcome, and additional advantages are provided through the provision, in one aspect, of a method for fabricating an interface passivation layer over a substrate, the fabricating including: providing a substrate; growing a silicon-germanium layer over the substrate; removing a native-oxide layer from an upper surface of the silicon-germanium layer; and exposing the upper surface of the silicon-germanium film to an ozone-containing solution, the exposing controllably oxidizing the upper surface to form the interface passivation layer, and the exposing resulting in a concentration of germanium-dioxide greater than a concentration of germanium-oxide in the interface passivation layer.

Also provided herein, in another aspect, is a structure including a gate structure over a substrate, the gate structure including: a channel region over the substrate, the channel region including silicon-germanium; and an interface passivation layer over the channel region, the interface passivation layer including, at least in part, germanium-oxide (GeO) and germanium-dioxide (GeO₂), wherein a concentration of the germanium-dioxide is higher than the concentration of the germanium-oxide.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 outlines a process for fabricating an interface passivation layer over a substrate, in accordance with one or more aspects of the present invention;

FIGS. 2A-2F depict one embodiment of a process for fabricating an interface passivation layer over a substrate, wherein a native oxide layer is removed from over a silicon-germanium layer and an interface passivation layer is formed, in accordance with one or more aspects of the present invention;

FIG. 3A is a graphical comparison of relative amounts of germanium, germanium-oxide, and germanium-dioxide present in an interface passivation layer, as a function of ozone concentration, formed from a silicon-germanium layer including 30% germanium, in accordance with one or more aspects of the present invention;

FIG. 3B is a graphical comparison of relative amounts of germanium, germanium-oxide, and germanium-dioxide present in an interface passivation layer, as a function of ozone concentration, formed from a silicon-germanium layer including 70% germanium, in accordance with one or more aspects of the present invention; and

FIG. 3C is a graphical comparison of ratios of germanium-dioxide to germanium-oxide present in an interface passivation layer, as a function of ozone concentration, for silicon-germanium layers with differing germanium concentrations, in accordance with one or more aspects of the present invention.

### DETAILED DESCRIPTION

Aspects of the present invention and certain features, advantages, and details thereof, are explained more fully below with reference to the non-limiting examples illustrated in the accompanying drawings. Descriptions of well-known materials, fabrication tools, processing techniques, etc, are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Silicon is often used as a channel material in metal-oxide semiconductor (MOS) transistors, such as metal-oxide semiconductor field-effect transistors (MOSFETs), but alternative channel materials have been used more recently to improve transistor performance and efficiency. Silicon-germanium is one exemplary channel material used in MOSFETs due to its superior electrical and physical properties, such as greater electric carrier mobility than that of silicon. One of the challenges in fabricating MOSFETs with silicon-germanium channels is the formation of a high-quality, defect-free interface passivation layer (IPL) between the silicon-germanium channel material and the gate dielectric material. Silicon-germanium channel layers may be formed, for example, by epitaxially growing a silicon-germanium layer over a semiconductor substrate, such as a bulk silicon wafer, and a native oxide layer generally forms on the silicon-germanium layer during or after formation. The native oxide layer generally includes both silicon-dioxide and germanium-oxide, with little or no germanium-dioxide included. Such a native oxide layer may, however, provide a poor interface passivation layer in a gate structure. The native oxide layer may, for example, present a large number of defects at the interfaces with the silicon-germanium layer beneath, have an uneven surface texture and layer thickness, and/or inhibit conductivity within the channel.

Thus, generally stated, provided herein in one aspect is a method of fabricating an interface passivation layer over a substrate, the fabricating including: providing a substrate; growing a silicon-germanium layer over the substrate; removing a native-oxide layer from an upper surface of the silicon-germanium layer; and exposing the upper surface of the silicon-germanium layer to an ozone-containing solution, the exposing controllably oxidizing the upper surface to form the interface passivation layer, and the exposing resulting in a concentration of germanium-dioxide greater than a concentration of germanium-oxide in the interface passivation layer.

In one exemplary embodiment, the ozone-containing solution may be de-ionized ozonated water (DI-O₃). Exposing the silicon-germanium layer to the ozone-containing solution may, for example, be carried out in a non-oxidizing environment. In another exemplary embodiment, the native oxide may be removed by exposing the native oxide layer to one or more acid solutions, such as hydrofluoric acid and/or hydrochloric acid. Removal of the native oxide layer may be performed in a non-oxidizing environment.

In another aspect, also provided herein is a structure including a gate structure over a substrate, the gate structure including: a channel region over the substrate, the channel region including silicon-germanium; and an interface passivation layer over the channel region, the interface passivation layer including, at least in part, germanium-oxide (GeO) and germanium-dioxide (GeO₂), wherein a concentration of the germanium-dioxide is higher than the concentration of the germanium-oxide

Reference is made below to the drawings, which are not drawn to scale for ease of understanding, wherein the same reference numbers used throughout different figures designate the same or similar components.

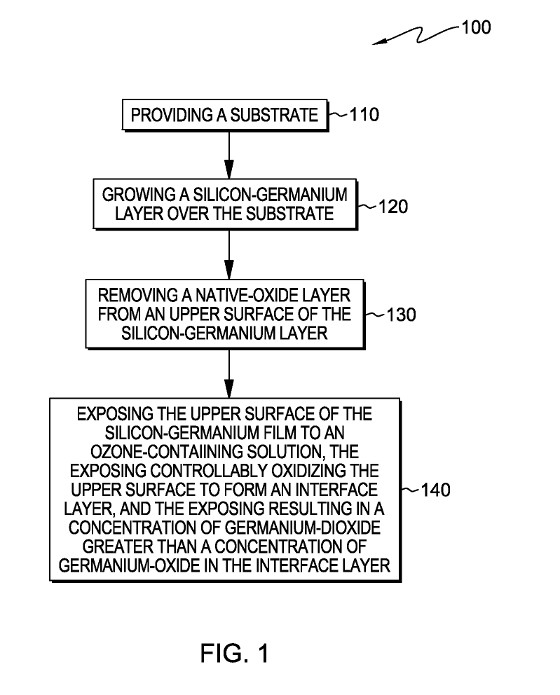

By way of summary, FIG. 1 illustrates one embodiment of a process 100 for fabricating a circuit structure, in accordance with one or more aspects of the present invention. In the embodiment illustrated, the process includes, for example: providing a substrate 100; growing a silicon-germanium layer over the substrate 110; removing a native oxide layer from an upper surface of the silicon-germanium layer 120; and exposing the upper surface of the silicon-germanium film to an ozone-containing solution, the exposing controllably oxidizing the upper surface to form an interface passivation layer, and the exposing resulting in a concentration of germanium-dioxide greater than a concentration of germanium-oxide in the interface passivation layer.

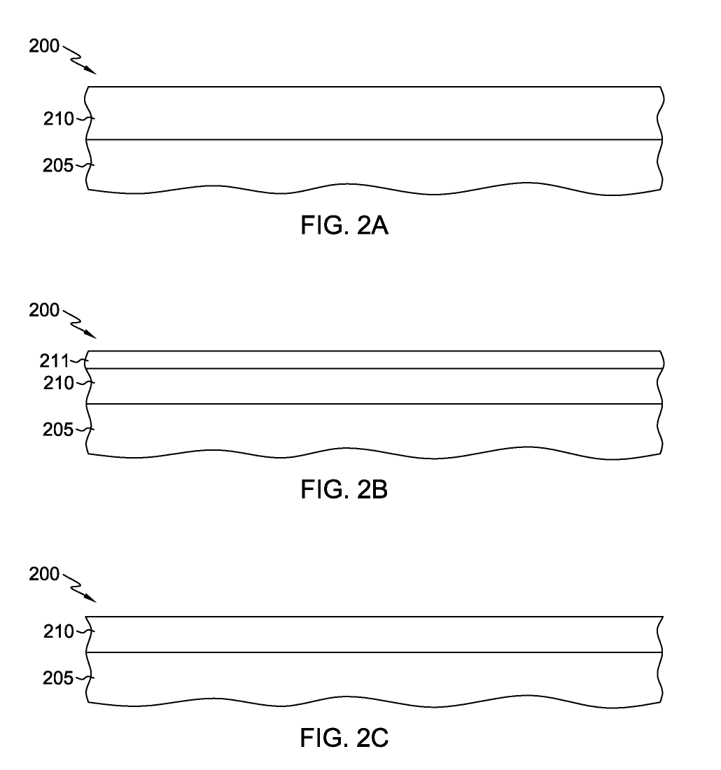

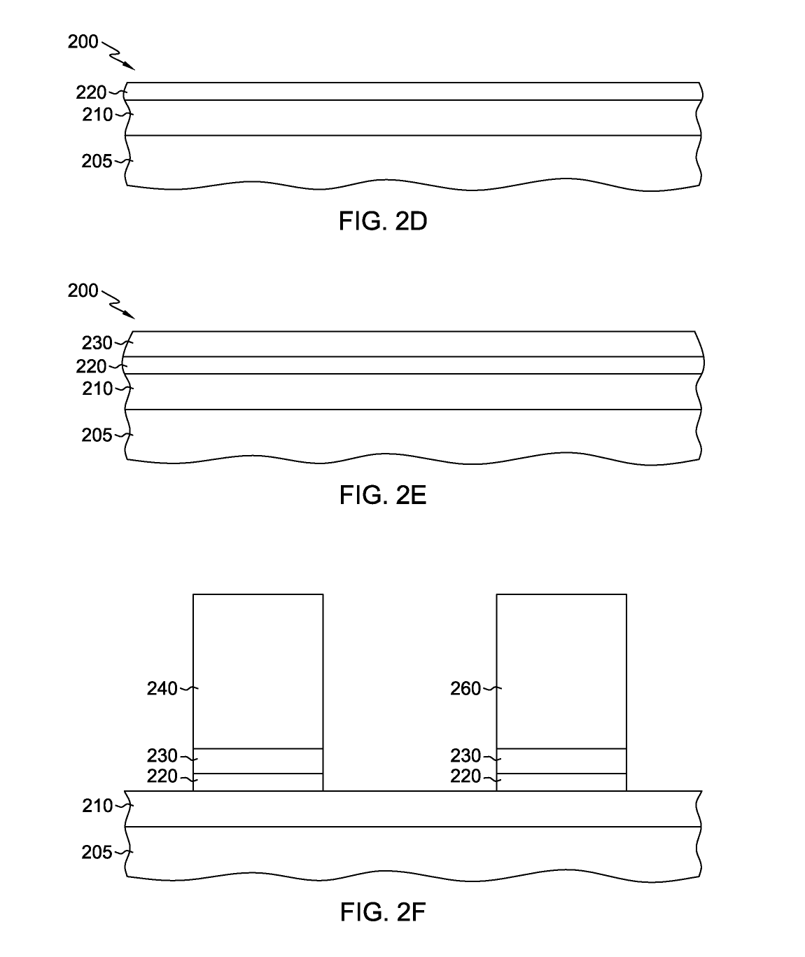

FIGS. 2A-2F depict one embodiment of the process described in FIG. 1 for forming an interface passivation layer over a substrate. FIG. 2A depicts a structure 200 including a substrate 205 and a silicon-germanium layer 210 over substrate 205. In one example, substrate 205 may be a silicon substrate, such as a bulk silicon wafer or a silicon-on-insulator (SOI) substrate. Silicon-germanium layer 210 may be provided, for example, by various epitaxial growth processes such as ultra-high vacuum chemical vapor deposition (UHV-CVD), low-pressure CVD (LPCVD), reduced-pressure CVD (RPCVD), rapid thermal CVD (RTCVD), or molecular beam epitaxy (MBE). Silicon-germanium may be expressed as Si₁₋ₓGeₓ wherein x, the atomic ratio of germanium to silicon, may be less than or substantially equal to about 1, although the atomic ratio in many silicon-germanium layers may range, in one example, from about 0.2 to about 0.8. In one exemplary embodiment, the ratio x of germanium to silicon may be about 0.7 or higher, at least in an upper portion of silicon-germanium layer 210. A ratio of about 0.7 or higher of germanium to silicon may advantageously increase the amount of germanium-dioxide resulting in the interface passivation layer to be formed, according to the processes described herein.

FIG. 2B depicts structure 200 of FIG. 2A with a native oxide layer 211 formed over an upper surface over silicon-germanium layer 210. Native oxide layer 211 may form, for example, as a result of exposure of an outer or upper surface of silicon-germanium layer 210 to atmosphere. Native oxide layer 211 may include silicon-dioxide (SiO₂) and germanium-oxide (GeO) in varying amounts. Due to the uncontrolled nature of the formation of native oxide layer 211, the native oxide layer 211 may have an uneven surface texture and/or may vary in thickness over silicon-germanium layer 210.

FIG. 2C depicts structure 200 of FIG. 2B following removal of native-oxide layer 211 from the upper surface of silicon-germanium layer 210. Removal of native-oxide layer 211 may include exposing native oxide layer 211 to one or more acid solutions. The removal of the native-oxide layer may, in exemplary embodiments, be performed in a non-oxidizing environment to prevent formation of another native-oxide layer following removal of the first native-oxide layer. An exemplary non-oxidizing environment may include 0.1% or less oxygen to effectively prevent regrowth of a native-oxide layer on silicon-germanium. The one or more acid solutions may include, for instance, hydrofluoric acid or hydrochloric acid. The one or more acid solutions may be provided in controlled concentrations and for controlled lengths of exposure time to effectively remove the entire native-oxide layer 211 from over silicon-germanium layer 210 without significantly affecting the silicon-germanium layer 210. In one embodiment, multiple acid solutions may be used in succession to effectively remove native-oxide layer 211. In an exemplary embodiment, native-oxide layer 211 may be removed by exposing native-oxide layer 211 to hydrofluoric acid (HF) with a 300:1 concentration for about 60 seconds, followed by exposing native-oxide layer 211 to hydrochloric acid (HCl) with a 100:1 concentration for about 60 seconds. The removal may ideally be performed at ordinary “room temperature,” as such temperatures may be less likely to promote regrowth of a native-oxide layer on silicon-germanium layer 210.

FIG. 2D depicts structure 200 of FIG. 2C following formation of interface passivation layer 220 over silicon-germanium layer 210. Interface passivation layer 220 may be formed, in one exemplary embodiment, by exposing the upper surface of silicon-germanium layer 210 to an ozone-containing solution, so that the ozone-containing solution controllably oxidizes the upper surface and forms the interface passivation layer 220. Exposure to the ozone-containing solution may result in a greater concentration of germanium-dioxide (GeO₂) in interface passivation layer 220 than the concentration of germanium-oxide (GeO) in interface passivation layer 220. Achieving a greater concentration of GeO₂ and a lower concentration of GeO may, for example, result in minimizing defects in the formed interface passivation layer 220, such as at the interface with silicon-germanium layer 220 as well as at an interface with a dielectric layer formed over the interface passivation layer 220.

The ozone-containing solution may be, for example, de-ionized ozonated water, which may be expressed as DI-O₃, with an ozone concentration selected to increase the concentration of germanium-dioxide and minimize the concentration of germanium-oxide in the interface passivation layer. The ozone concentration may range, for example, from about 5 ppm to about 20 ppm or higher. The ozone concentration selected may depend, in part, on the ratio of germanium to silicon in the silicon-germanium layer 210, as the amount of germanium in the silicon-germanium layer may partially determine the amount of germanium-dioxide formed in the resulting interface passivation layer 220. The ozone concentration selected may also depend, in part, on a desired resulting thickness of interface passivation layer 220. In exemplary embodiments, the concentration of ozone may be selected to minimize a thickness of interface passivation layer 220, as keeping the thickness of the interface passivation layer 220 as small as possible may advantageously improve one or more electrical properties of the interface passivation layer 220 as well as of a gate structure that incorporates part of interface passivation layer 220. For example, interface passivation layers in gate structures may act as inversion layers in completed transistor structures, and minimizing the size of the inversion layer in the gate structure may improve electrical performance of the gate and transistor structure. In exemplary embodiments, the thickness of the interface passivation layer may be 1.5 nm or less.

Exposing the upper surface of silicon-germanium layer 210 to the ozone-containing solution may also include controlling the exposure time, with the controlled exposure time selected to increase the concentration of germanium-dioxide and minimize the concentration of germanium-oxide in the resulting interface passivation layer 220. The controlled exposure time may range, for example, from about 10 seconds to about 90 seconds, depending in part on the ratio of germanium to silicon in the silicon-germanium layer 210 as well as the selected concentration of ozone in the ozone-containing solution. The exposure time selected may also depend, in part, on the desired resulting thickness of interface passivation layer 220. In one embodiment, the exposure time may be selected to minimize a thickness of interface passivation layer 220. In another embodiment, in which the silicon-germanium 220 layer forms, in part, a channel of a gate structure, the controlled exposure time may be selected to increase mobility of electrical charge carriers in the channel. Those with skill in the art may appreciate that, in some embodiments, selecting an optimal exposure time may involve trading off carrier mobility for a thinner interface passivation layer, or vice versa, as a longer exposure time may, for example, help increase carrier mobility but also result in an increased thickness of the interface passivation layer.

In one exemplary embodiment, exposing the upper surface of the silicon-germanium layer 210 to the ozone-containing solution, such as DI-O₃, may be performed in a non-oxidizing environment. The non-oxidizing environment may, for instance, include 0.1% oxygen or less. Exposing the silicon-germanium layer 210 to the ozone-containing solution in a non-oxidizing environment may further facilitate control of the oxidation of silicon-germanium layer 210 to form interface passivation layer 220, as the oxidation of the silicon-germanium layer 210 may occur primarily through chemical interaction with the ozone in the ozone-containing solution rather than through interaction with, for example, atmospheric oxygen.

FIG. 2E depicts structure 200 of FIG. 2D following provision of a dielectric layer 230 having a high dielectric constant k over interface passivation layer 220. In exemplary embodiments, the greater concentration of GeO₂ and lower concentration of GeO in interface passivation layer 210 may permit several types of dielectric layer materials to be provided over the interface passivation layer 210. The dielectric layer may include one or more of aluminum oxide (Al₂O₃), hafnium oxide (HfO₂), titanium oxide (TiO₂), zirconium oxide (ZrO₂), yttrium oxide (Y₂O₃), or lanthanum oxide (La₂O₃). Other dielectric layer materials having a high dielectric constant k may also be used in alternative embodiments.

FIG. 2F depicts structure 200 of FIG. 2E with one or more gate stacks 240 provided over one or more portions of dielectric layer 230 and interface passivation layer 220. Gate stack 240, at least a portion interface passivation layer 220, and at least a portion of dielectric layer 230 may together form part of a gate structure, such as a gate structure of a transistor circuit structure. At least a portion of silicon-germanium layer 210 below gate stack 240 may form a channel region of the gate structure. FIG. 2F depicts one exemplary embodiment of structure 200 in which a portion of interface passivation layer 220 and dielectric layer 230 have been etched away to expose portions of silicon-germanium layer 210, allowing for subsequent processing of portions of silicon-germanium layer 210, such as dopant implantation to form source/drain regions. It may be understood that in alternative embodiments other portions of interface passivation layer 220 and dielectric layer 230 may be removed, or such layers may be left intact. Gate stack 240 may include one or more gate stack materials, such as a gate work-function material, gate metal, or other materials to form a desired gate stack 240.

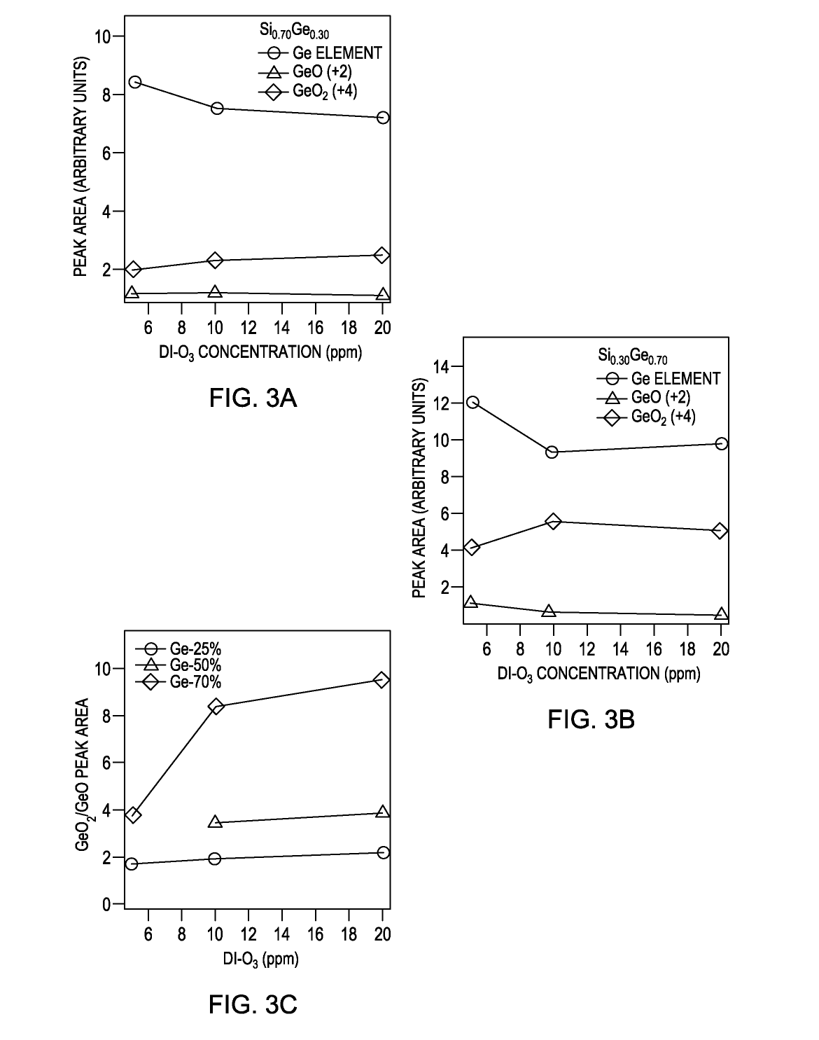

FIGS. 3A-3C are graphs comparing relative amounts or ratios of germanium-dioxide present in an interface passivation layer formed from a silicon-germanium layer, according to methods described herein, for different concentrations of ozone in a de-ionized water (DI-O₃) solution. The chart in FIG. 3A compares amounts of germanium-dioxide to amounts of germanium-oxide and germanium in an interface passivation layer formed from a silicon-germanium layer including 70% silicon and 30% germanium (Si_{0.70}Ge_{0.30}), while the chart in FIG. 3B provides the same comparison for an interface passivation layer formed from a silicon germanium layer including 30% silicon and 70% germanium (Si_{0.30}Ge_{0.70}). In each case, the exposure time was approximately 60 seconds. For the Si_{0.70}Ge_{0.30} layer in FIG. 3A, the interface passivation layer may be optimally formed with a concentration of ozone close to 20 ppm as this level of ozone provides the greatest concentration of germanium-dioxide in the resulting interface passivation layer. For the Si_{0.30}Ge_{0.70} layer in FIG. 3B, however, the optimal concentration of ozone may be closer to about 10 ppm. As these charts demonstrate, the ozone concentration level chosen for forming the interface passivation layer may depend, in part, on the initial concentration of germanium present in the silicon-germanium layer, and may not always optimally be the highest concentration possible for ozonated water. It may be noted, as described above, that an optimal ozone concentration chosen may also depend, in part, on the desired resulting thickness of the interface passivation layer. As well, the time of exposure of the silicon-germanium layer may be varied to achieve a desired interface passivation layer thickness as well as germanium-dioxide concentration in the interface passivation layer.

FIG. 3C provides a comparison of germanium-dioxide to germanium-oxide ratios achievable in interface passivation layers formed from silicon-germanium layers of differing germanium levels, from about 25% germanium to 70% germanium, as a function of ozone concentration. As with FIGS. 3A and 3B, the exposure time here was approximately 60 seconds. As FIG. 3C illustrates, the relative amount of germanium present in the silicon-germanium layer prior to processing can have a significant impact on the resulting relative amounts of germanium-dioxide and germanium-oxide in the final interface passivation layer. For example, for a layer including only about 25% germanium, the ratio of germanium-dioxide to germanium-oxide in the interface passivation layer increases only slightly with increasing ozone concentration in the DI-O₃ solution. However, for a layer including 50% to 70% germanium, an increase in ozone concentration strongly corresponds to a greater ratio of germanium-dioxide to germanium-oxide in the final interface passivation layer.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
fabricating an interface passivation layer over a substrate, the fabricating comprising:
providing a substrate;
growing a silicon-germanium layer over the substrate, wherein the silicon-germanium layer includes at least 50% germanium;
removing a native-oxide layer from an upper surface of the silicon-germanium layer; and
exposing the upper surface of the silicon-germanium layer to an ozone-containing solution, the exposing controllably oxidizing the upper surface to form the interface passivation layer, and the exposing resulting in a concentration of germanium-dioxide greater than a concentration of germanium-oxide in the interface passivation layer.

2. The method of claim 1, wherein the ozone-containing solution comprises a concentration of ozone selected to increase the concentration of germanium-dioxide and minimize the concentration of germanium-oxide in the interface passivation layer.

3. The method of claim 2, wherein the concentration of ozone is further selected to minimize a thickness of the interface passivation layer.

4. The method of claim 1, further comprising controlling an exposure time of the upper surface to the ozone-containing solution, the controlled exposure time selected to increase the concentration of germanium-dioxide and minimize the concentration of germanium-oxide in the interface passivation layer.

5. The method of claim 4, wherein the controlled exposure time is further selected to minimize a thickness of the interface passivation layer.

6. The method of claim 4, wherein the silicon-germanium layer forms, in part, a channel region of a gate structure, and wherein the controlled exposure time is further selected to increase a mobility of electrical charge carriers in the channel region.

7. The method of claim 1, wherein the exposing resulting in a concentration of germanium-dioxide greater than a concentration of germanium-oxide in the interface passivation layer minimizes defects in the interface passivation layer.

8. The method of claim 1, wherein exposing the upper surface of the silicon-germanium film to an ozone-containing solution is performed in a non-oxidizing environment.

9. The method of claim 8, wherein the non-oxidizing environment comprises 0.1% oxygen or less.

10. The method of claim 1, wherein the ozone-containing solution comprises de-ionized ozonated water.

11. The method of claim 1, wherein the removing comprises exposing the native-oxide layer to one or more acid solutions.

12. The method of claim 11, wherein the removing is performed in a non-oxidizing environment.

13. The method of claim 12, wherein the non-oxidizing environment comprises 0.1% oxygen or less.

14. The method of claim 11, wherein the one or more acid solutions include hydrofluoric acid.

15. The method of claim 11, wherein the one or more acid solutions include hydrochloric acid.

16. The method of claim 1, further comprising depositing a dielectric layer having a high dielectric constant over the interface passivation layer.

17. The method of claim 16, wherein the dielectric layer comprises one or more of aluminum oxide (Al₂O₃), hafnium oxide (HfO₂), titanium oxide (TiO₂), zirconium oxide (ZrO₂), yttrium oxide (Y₂O₃), or lanthanum oxide (La₂O₃).

18. A structure comprising:
a gate structure over a substrate, the gate structure comprising:
a channel region over the substrate, the channel region comprising silicon-germanium, the channel region including at least 50% germanium; and
an interface passivation layer over the channel region, the interface passivation layer comprising, at least in part, germanium-oxide (GeO) and germanium-dioxide (GeO₂), wherein a concentration of the germanium-dioxide is higher than the concentration of the germanium-oxide.

19. The structure of claim 18, further comprising a dielectric layer above the interface passivation layer, the dielectric layer having a high dielectric constant.

20. The structure of claim 18, wherein a thickness of the interface passivation layer is 1.5 nm or less.
